(19) United States
(12) Patent Application Publication
(10) Pub. No.: US 2011/0023931 A1
(43) Pub. Date: Feb. 3, 2011

(54) SOLAR ENERGY STORAGE DEVICE WITH ANGLE-ADJUSTABLE SOLAR PANEL

(76) Inventor: Juei-Chao CHEN, Taipei (TW)

Correspondence Address: Juei-Chao CHEN, P.O.BOX 46-563 Taipei, Taipei City, 10499, TW

(21) Appl. No.: 12/512,042

(22) Filed: Jul. 30, 2009

(51) Int. Cl. H01L 31/042

(52) U.S. Cl. 136/244

(57) ABSTRACT

A solar energy storage device with an angle-adjustable solar panel includes the solar panel, at least two fixed supporters, at least one battery, at least one transmission interface, and at least two movable supporters. The fixed supporters and the movable supporters jointly prop up the solar panel so as to allow the solar panel to efficiently absorb solar energy and convert the solar energy into electric power. The converted electric power is stored in the battery to be later supplied to an external device that consumes electric power through the transmission interface.

### BACKGROUND OF THE INVENTION

1. Technical Field

The present invention relates to solar energy storage devices, and more particularly, to a solar energy storage device with an angle-adjustable solar panel.

2. Description of Related Art

Presently, the global environment and all human beings are facing severe survival tests. In view of global warming and energy crisis that have seriously impacted our daily life, the governments rush on to develop technologies for addressing or mitigating these problems without exception. Therein, solar application is regarded momentous because it adds no additional burden or pollution to the environment However, the poor energy conversion efficiency is the Achilles' heel of the existing solar power products. In addition to technical limitations, the variation of solar beam incidence angle with time is also an attributable cause of such poor energy conversion efficiency performed by the existing solar power products. Since the conventional solar power devices typically have solar panels fixed at predetermined angles, the solar panels are unable to cater for real-time sunshine condition. Therefore, the conventional solar power devices only have a short period of sunlight exposure, and only a limited amount of solar energy can be collected. As a result, the energy collection efficiency of the conventional solar power devices is significantly restricted.

### SUMMARY OF THE INVENTION

The primary objective of the present invention is to provide a solar energy storage device with an angle-adjustable solar panel. The solar energy storage device includes the solar panel, at least two fixed supporters, at least one battery, at least one transmission interface, and at least two movable supporters. The fixed supporters and the movable supporters jointly prop up the solar panel so as to allow the solar panel to act as a sunshade and efficiently absorb solar energy when the solar energy storage device is installed outdoors. Then the absorbed solar energy can be converted into electric power and stored in the battery so to be later supplied to an external device that consumes electric power through the transmission interface.

The secondary objective of the present invention is to provide the solar energy storage device wherein each of the fixed supporters and the movable supporters is provided with an adjuster for adjusting the height of the fixed supporter or the length of the movable supporter so that the solar panel can be posed at different angles and heights, thereby ensuring the optimal light absorbing efficiency.

### BRIEF DESCRIPTION OF THE DRAWINGS

The invention as well as a preferred mode of use, further objectives and advantages thereof will be best understood by reference to the following detailed description of an illustrative embodiment when acquire in conjunction with the accompanying drawings, wherein:

FIG. 1 is a perspective view of a solar energy storage device according to the present invention;

FIG. 2 is an exploded view of the solar energy storage device according to the present invention;

FIG. 3 is a partial schematic drawing of the solar energy storage device according to the present invention; and

FIGS. 4 through 8 are applied views of the solar energy storage device according to the present invention.

### DETAILED DESCRIPTION OF THE PREFERRED EMBODIMENT

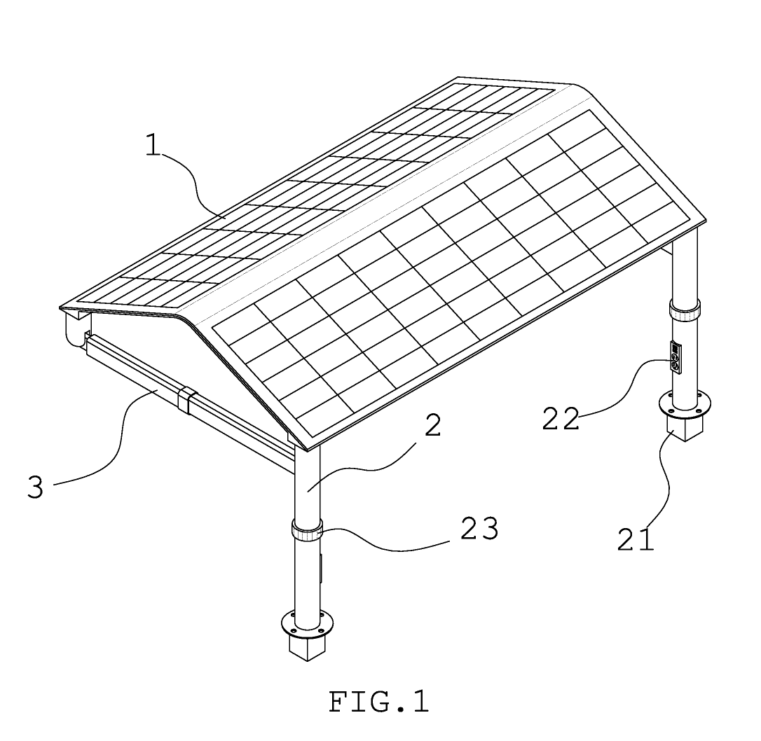

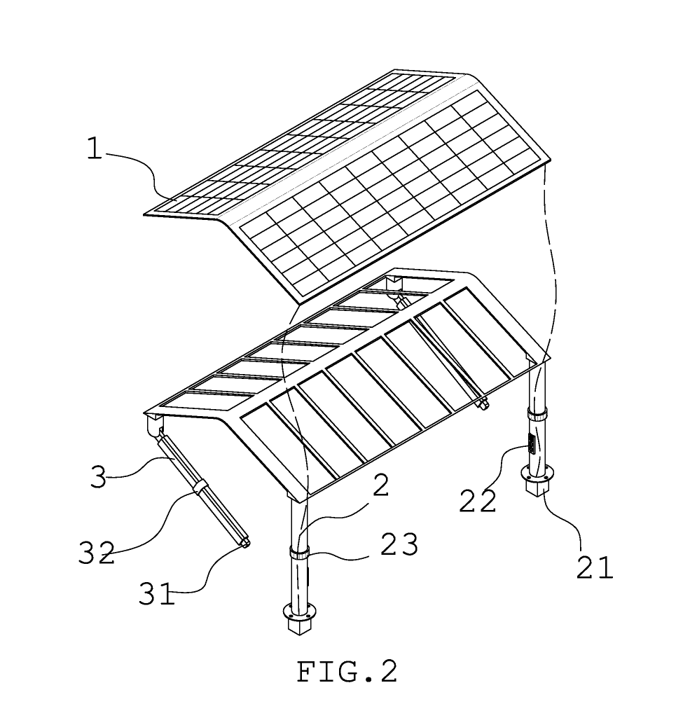

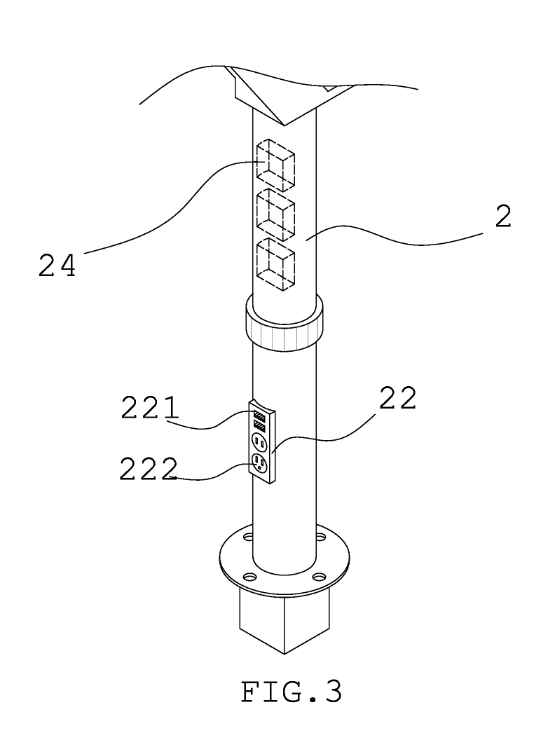

Please refer to FIGS. 1, 2 and 3 for a perspective view, an exploded view and a partial schematic drawing of a solar energy storage device according to the present invention. The solar energy storage device primarily includes a solar panel 1, at least two fixed supporters 2, at least one battery 21, at least one transmission interface 22, and at least two movable supporters 3.

The solar panel 1 may be a monocrystalline silicon solar panel, a polycrystalline silicon solar panel, an amorphous silicon solar panel, a flexible GaAs solar panel, a CIGS solar panel, a multi-junction tandem solar panel or any solar panel with applicable specifications.

According to the drawing, the two fixed supporters 2 are connected to a lower surface of the solar panel 1 for supporting the solar panel 1. Each said fixed supporter 2 is provided with an adjuster 23 for adjusting the height thereof. Furthermore, each said fixed supporter 2 has at least mortise 24. In the present embodiment, there are three mortises 24 formed on each of the fixed supporters 2.

The battery 21 maybe a Ni—H battery, an alkaline battery, a mercury battery, a Ni—Cd battery, a lithium battery, a lithium-polymer battery or any battery capable of storing electric power. The battery 21 is removably coupled with one of the fixed supporters 2 for storing the electric power converted from the solar energy absorbed by the solar panel 1.

Each said transmission interface 22 is deposited on a respective said fixed supporter 2 and includes at least one USB socket 221 and at least one outlet 222.

The movable supporters 3 are connected to one side of the solar panel 1 and are designed to engage with the fixed supporters 2 to prop up the solar panel 1. Each said movable supporter 3 has a tenon 31 and an adjuster 32 for allowing the movable supporter 3 to be adjusted in length.

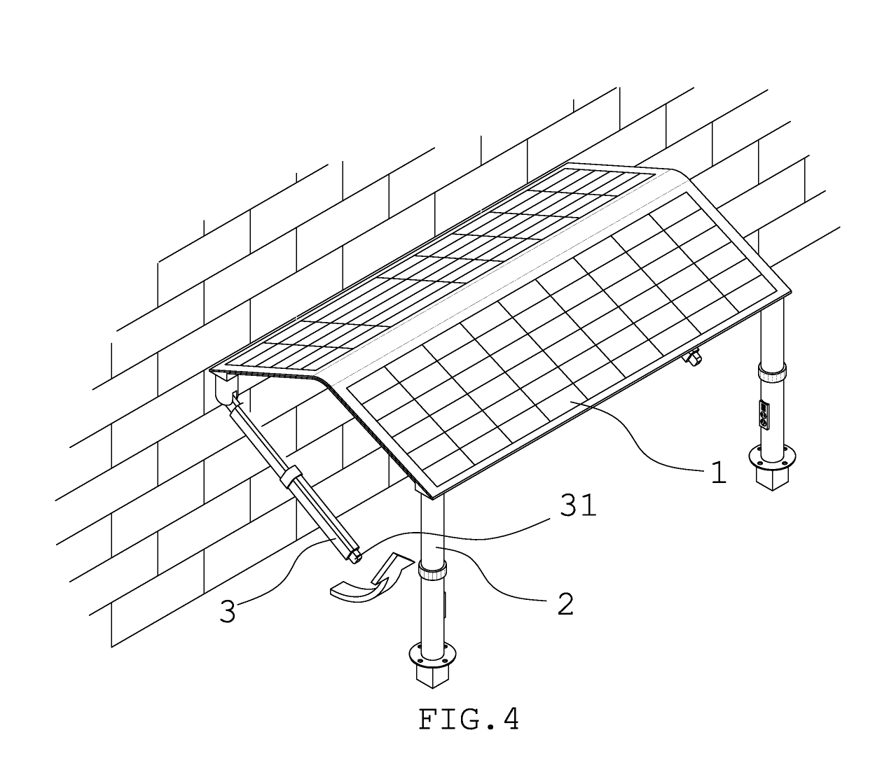

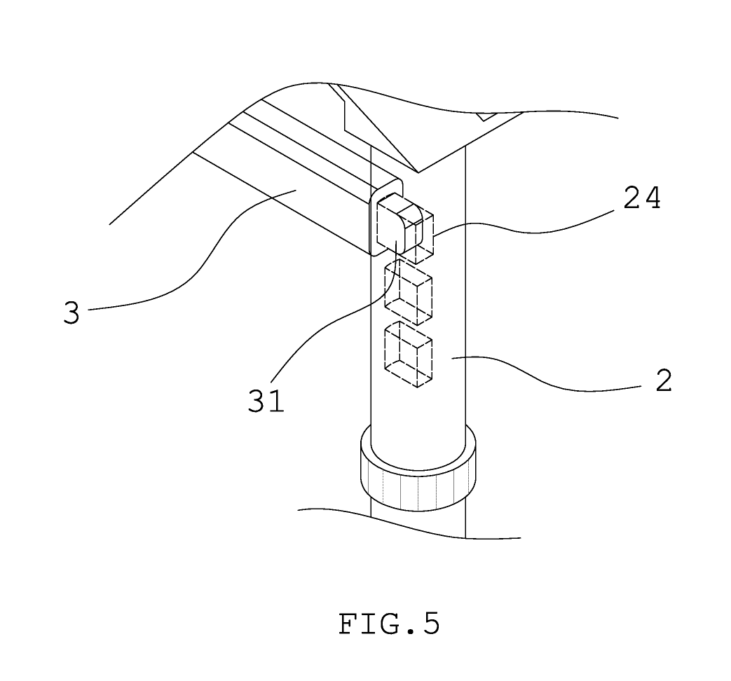

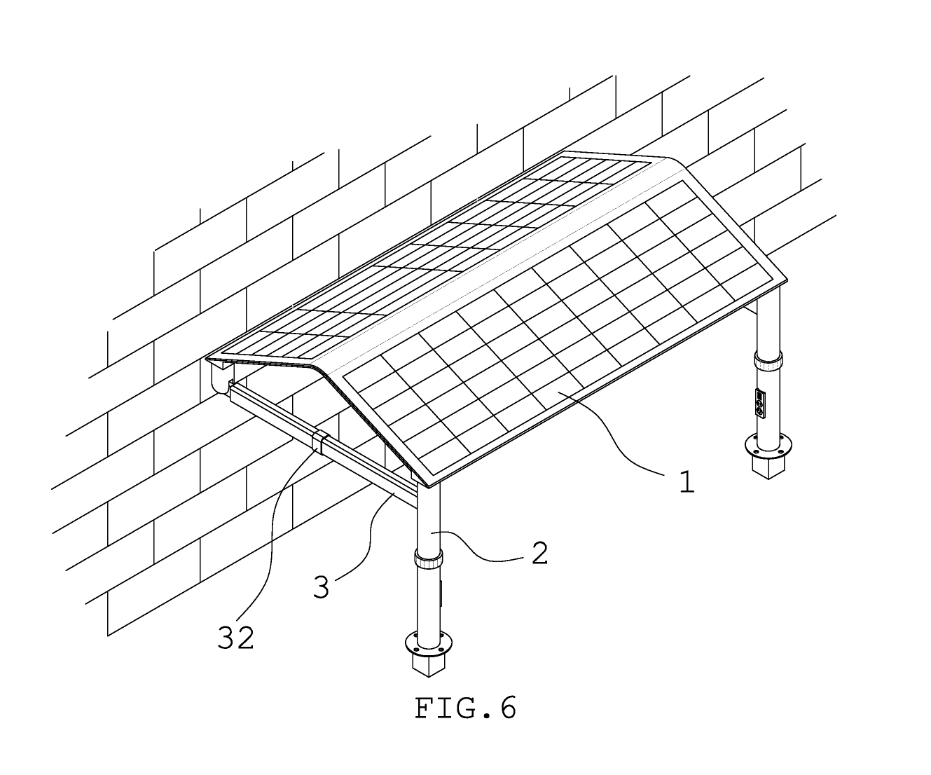

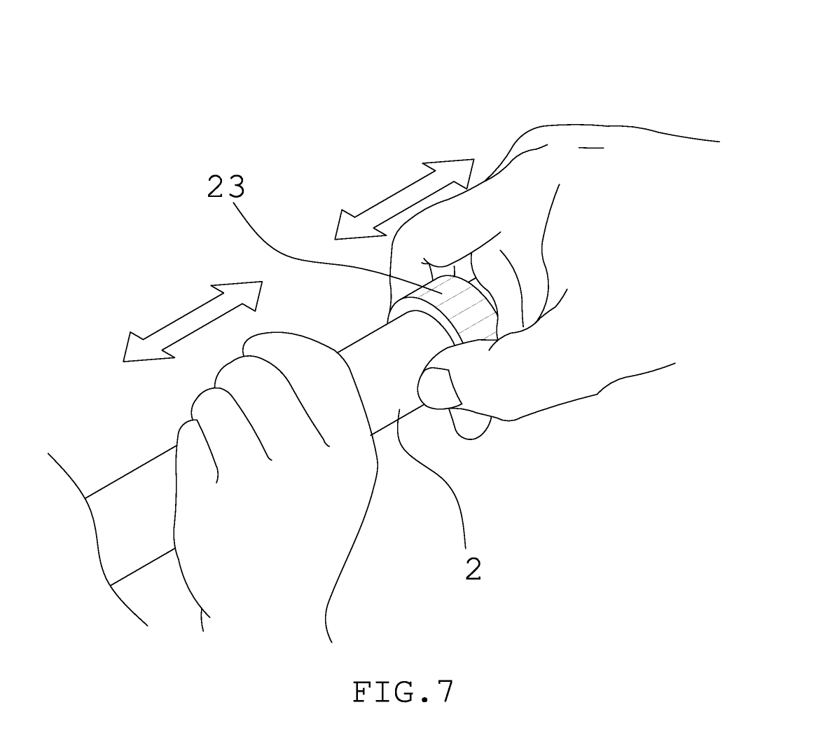

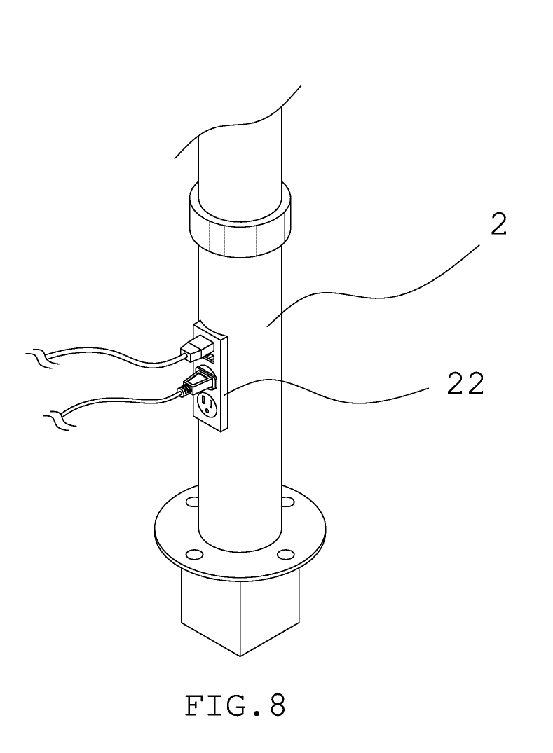

Please refer to FIGS. 4, 5, 6, 7 and 8 for applied views of the solar energy storage device. As can be seen clearly in the drawings, the tenons 31 located at ends of the movable supporters 3 are inserted into the corresponding mortises 24 formed on the fixed supporters 2 so as to combine the movable supporters 3 with the fixed supporters 2 and thus prop up the solar panel 1. Thereby, the solar panel 1 not only serves as a sunshade, but also efficiently absorbs solar energy and converts the same into electric power. Then the electric power stored in the battery 21 that is coupled with the fixed supporter 2 can be further supplied to an external device, such as a mobile phone, a PDA, an MP3, a small fan, a lighting device, or an advertisement lamp, through the transmission interface 22 on the fixed supporter 2. The power output specifications of the USB socket 221 and the outlet 222 may be determined by the charging requirements of the external device. Moreover, the adjusters 23 on the fixed supporters 2 allow height adjustment of the fixed supporters 2 while the adjusters 32 on the movable supporters 3 allow the length adjustment of the movable supporters 3. Meantime, the tenons 31 at ends of the movable supporters 3 can be inserted into the mortises 24 at desired heights so that the solar panel 1 can be posed at any angle best catering for the solar beam incidence angle, thereby achieving the optimal solar absorbing efficiency.

To sum up, the solar energy storage device provided in the present invention allows the solar panel 1 to act as a sunshade while efficiently absorbing solar energy. The solar energy storage device then converts the absorbed solar energy into electric power to be supplied to various external devices. Thus, when installed outdoors, the solar energy storage device provides improved convenience in power supply and facilitates saving grid electricity.

What is claimed is:

1. A solar energy storage device with an angle-adjustable solar panel, the solar energy storage device comprising:
a solar panel;
at least two fixed supporters connected to a lower surface of the solar panel for supporting the solar panel;
at least a battery coupled with one of the fixed supporters for storing electric power converted from solar energy absorbed by the solar panel;
at least one transmission interface deposited on the fixed supporter for supplying the electric power stored in the battery to an external device; and
at least two movable supporters coupled to one side of the solar panel and designed to engage with the fixed supporters for jointly propping up the solar panel.

2. The solar energy storage device of claim 1, wherein the solar panel is a monocrystalline silicon solar panel, a polycrystalline silicon solar panel, an amorphous silicon solar panel, a flexible GaAs solar panel, a CIGS solar panel, or a multi-junction tandem solar panel,

3. The solar energy storage device of claim 1, wherein the battery is a Ni—H battery, an alkaline battery, a mercury battery, a Ni—Cd battery, a lithium battery, or a lithium-polymer battery.

4. The solar energy storage device of claim 1, wherein each of the fixed supporters has at least one adjuster.

5. The solar energy storage device of claim 1, wherein the battery is removably coupled to the fixed supporter.

6. The solar energy storage device of claim 1, wherein the transmission interface includes at least one USB socket and at least one outlet.

7. The solar energy storage device of claim 1, wherein the fixed supporter is provided with at least one mortise while the movable supporter is provided with at least one tenon.

8. The solar energy storage device of claim 1, wherein each of the movable supporters has at least one adjuster.
